(19) United States
(12) Patent Application Publication
(10) Pub. No.: US 2022/0132674 A1
(43) Pub. Date: Apr. 28, 2022

(54) PRINTED WIRING BOARD

(71) Applicant: Mitsubishi Electric Corporation, Tokyo (JP)

(72) Inventors: Koji SHIGETA, Tokyo (JP); Suguru KADOYA, Tokyo (JP); Tomotaka KOJIMA, Tokyo (JP); Daisuke ITO, Tokyo (JP)

(21) Appl. No.: 17/422,788

(22) PCT Filed: Mar. 27, 2019
(86) PCT No.: PCT/JP2019/013443

§ 371 Date: Jul. 14, 2021

(51) Int. Cl. H05K 3/34; H05K 1/11; H05K 1/18; B23K 1/00; B23K 1/012

(52) U.S. Cl. CPC H05K 3/3421; H05K 1/111; H05K 1/181; B23K 2101/42; B23K 1/012; H05K 2201/2081; B23K 1/0016

(57) ABSTRACT

A printed wiring board to which an electronic component is soldered by a jet soldering device, the printed wiring board includes as insulating substrate, a land provided on one surface of the insulating substrate, the one surface serving as a soldering surface, a through hole provided in the land and passing through the insulating substrate in a thickness direction of the insulating substrate. A lead of the electronic component is inserted into the through hole from the other surface of the insulating substrate, the other surface is opposed to the one surface, and an auxiliary conductor is provided in a region of a plane on the one surface, the region is adjacent to the land in a predetermined direction. The auxiliary conductor is provided to have a width equal to a width of the land in the same region of the plane.

### CROSS REFERENCE TO RELATED APPLICATION

This application is a U.S. National Stage Application of International Patent Application No. PCT/JP2019/013443 filed on Mar. 27, 2019, the disclosure of which is incorporated herein by reference.

### TECHNICAL FIELD

The present invention relates to a printed wiring board including an electrode pad to which an electrode of an electronic component is soldered.

### BACKGROUND

There are soldering methods available to solder are electronic component to a printed wiring board, including a reflow soldering method and a flow soldering method. In the reflow soldering method, solder paste in which solder fine particles are kneaded with flux is printed on an electrode pad on a printed wiring board by a printer through a metal mask. A surface mount component that is an electronic component is positioned on the solder paste by a mounter. Thereafter, in a heating furnace called “reflow furnace”, the printed wiring board is heated to increase its temperature. This heating activates the flux mixed in the solder paste, and then an oxide coating is removed from the surface of an electrode of the surface mount component, so that the surface of the electrode is kept in a clean state. Thereafter, in the reflow furnace, the printed wiring board is conveyed to a zone heated to a temperature at which the solder fine particles melt. The electrode of the electronic component is thereby soldered to the electrode pad on the printed wiring board.

In contrast, in the flow soldering method, a target object to be soldered is immersed in molten solder. In this method, a lead of an electronic component that is an insertion mount component is inserted into a through hole on a printed wiring board, and then flux is applied to a solder-joint portion such as a through-hole land and the lead of the electronic component. The printed wiring board is then preheated in a soldering device, and thereafter jet solder in a molten state is brought into contact with the printed wiring board and the electronic component, so that the electronic component is soldered to the printed wiring board. The flow soldering method is also referred to as “jet soldering method”.

Meanwhile, there is a case where a surface mount component and an insertion mount component are both mounted on a single printed wiring board. In that case, a soldering method called “hybrid mounting” is sometimes employed for the purpose of reducing manufacturing costs. In this method, a surface mount component is positioned on an adhesive applied to one surface of the printed wiring board, and thereafter the adhesive is cured, so that the electronic component is temporarily fixed to the printed wiring board. Next, the printed wiring board is turned upside down, and then a lead of an insertion mount component is inserted into a through hole from the other surface of the printed wiring board. Thereafter, the surface mount component and the inserted component are soldered simultaneously to the printed wiring board with jet solder at once.

There are printed circuit boards in each of which various types of components are soldered to a printed wiring board. In some of the printed circuit boards, the solder-joint area between a lead of an electronic component and the printed wiring board may be relatively small originally, such as a single-sided printed wiring board on which through-hole plating is not formed. In some of the printed circuit boards, the solder-joint, amount by jet soldering may be insufficient. When such a printed circuit board as described above is incorporated into an electronic device, a temperature cycle occurs attributable to a temperature change in the atmosphere due to operation of the electronic device, and attributable to a temperature change in the atmosphere due to installation environment of the electronic device. A linear expansion coefficient mismatch between the electronic component and the printed wiring board in the temperature cycle may cause a crack in the solder-joint, portion. If the crack spreads, there is a risk of earlier fatigue failure, which may impair long-term reliability of the solder-joint portion.

To solve this problem, Patent Literature 1 discloses a circuit board including a substrate, an electronic component having a lead wire and provided on the substrate, and a conductive land provided in such a manner as to form a circuit on the substrate. On this circuit board, a plurality of induction lands intended to induce solder are provided on the forward side relative to the conductive land to be soldered with the lead wire in the feed direction of the substrate during soldering work. On the circuit board disclosed in Patent Literature 1, when an electronic component is soldered to the substrate by a flow soldering method, molten solder first comes into contact with the induction land disposed on the most forward side in the feed direction, and thereafter separates from this induction land and returns to a molten solder bath. Subsequently, the contact and separation of the molten solder is repeated with respect to the next induction land.

### Patent Literature

Patent Literature 1: Japanese Patent Application Laid-open No. H11-177232

However, in the circuit board disclosed in Patent Literature 1 described above, at a location where it is desired to increase the solder-joint amount, the molten solder sticking to the forward induction land cannot be conveyed over to the above described location. Therefore, the solder-joint amount cannot be increased. For this reason, in a temperature cycle that occurs after the circuit board has been incorporated into an electronic device, a linear expansion coefficient mismatch between the electronic component and the printed wiring board may cause a crack in the solder-joint portion. If the crack spreads, there is a risk of earlier fatigue failure, which may impair long-term reliability of the solder-joint portion.

### SUMMARY

The present invention has been achieved to solve the above problems, and an object of the present invention is to provide a printed wiring board that can increase the solder-joint amount for the printed wiring board and a component to be soldered to the printed wiring board, and that can ensure long-term reliability of a solder-joint portion between the printed wiring board and the component.

To solve the above problems and achieve the object, a printed wiring board according to the present invention is the printed wiring board to which an electronic component is soldered by a jet soldering device. The printed wiring board includes: an insulating substrate; a land provided on one surface of the insulating substrate, the one surface serving as a soldering surface; a through hole provided in the land and passing through the insulating substrate in a thickness direction of the insulating substrate, where a lead of the electronic component is inserted into the through hole from the other surface of the insulating substrate, the other surface being opposed to the one surface; and an auxiliary conductor provided in a region of a plane on the one surface, the region being adjacent to the land in a predetermined direction, the auxiliary conductor being provided to have a width equal to a width of the land in a same region of the plane on the one surface as a region where the land is formed in a direction perpendicular to the predetermined direction.

The printed wiring board according to the present invention has an advantageous effect where it is possible to increase the solder-joint amount for the printed wiring board and a component to be soldered to the printed wiring board, and that can ensure long-term reliability of a solder-joint portion between the printed wiring board and the component.

### BRIEF DESCRIPTION OF DRAWINGS

FIG. 1 is a plan view of relevant parts of a printed wiring board according to a first embodiment of the present invention.

FIG. 2 is a cross-sectional diagram taken along the line II-II in FIG. 1.

FIG. 3 is a schematic diagram illustrating a configuration of a jet soldering device according to the first embodiment of the present invention.

FIG. 4 is a schematic cross-sectional diagram illustrating an internal structure of a jet soldering unit in the jet soldering device according to the first embodiment of the present invention.

FIG. 5 is a diagram of the jet soldering device in which the printed wiring board is conveyed in a substrate conveying direction, and illustrates a state at a moment at which the printed wiring board comes into contact with the molten solder.

FIG. 6 is a diagram of the jet soldering device in which the printed wiring board is conveyed further forward, and a land, auxiliary conductors, and an electronic component lead come into contact with the molten solder, and illustrates a state at a moment at which the molten solder separates from the land, the auxiliary conductors, and the electronic component lead after the contact.

FIG. 7 is a diagram of the jet soldering device in a state in which the printed wiring board is conveyed even further forward, then soldering is completed with the molten solder having completely separated from the printed wiring board, and then a solder fillet is formed on the electronic component lead, the land, and the auxiliary conductors.

FIG. 8 is a side view illustrating the state illustrated in FIG. 6 when observed from the direction of a broken arrow A in FIG. 6.

FIG. 9 is a side view illustrating the state illustrated in FIG. 7 when observed from the direction of the broken arrow A in FIG. 7.

FIG. 10 is a cross-sectional diagram taken along the X-X line in FIG. 1 after the printed wiring board illustrated in FIG. 9 has been incorporated into an electronic device.

FIG. 11 is a plan view of relevant parts of a printed wiring board according to a second embodiment of the present invention.

FIG. 12 is a diagram corresponding to FIG. 8 in soldering of the electronic component to the printed wiring board.

### DETAILED DESCRIPTION

A printed wiring board according to embodiments of the present invention will be described in detail below with reference to the accompanying drawings. The present invention is not limited to the embodiments.

### First Embodiment

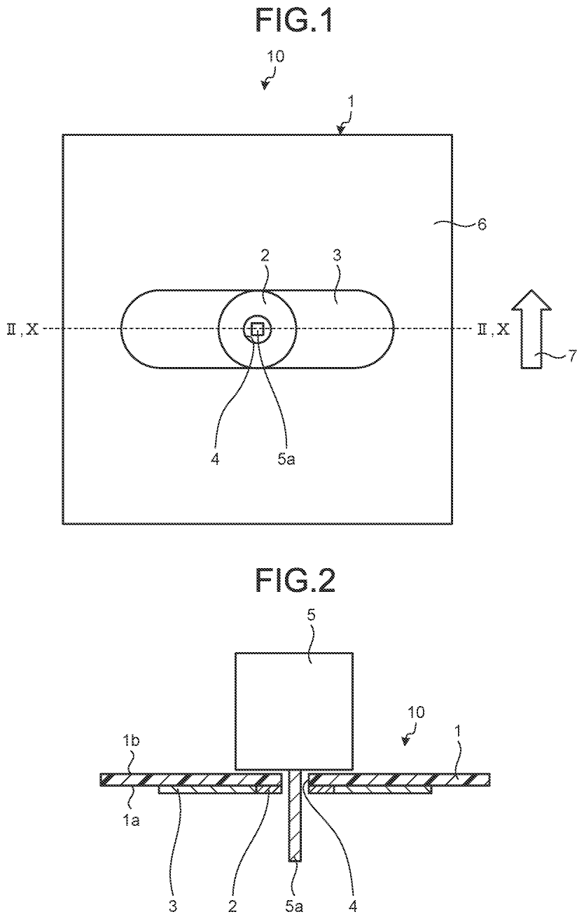

FIG. 1 is a plan view of relevant parts of a printed wiring board 10 according to a first embodiment of the present invention. FIG. 1 illustrates an enlarged region where a land 2 is formed on one surface la of the printed wiring board 10. FIG. 1 also illustrates the printed wiring board 10 with an electronic component lead 5a of an electronic component 5 inserted into a through hole 4 on the printed wiring board 10. FIG. 2 is a cross-sectional diagram taken along the line II-II in FIG. 1.

The printed wiring board 10 illustrated in FIG. 1 includes an insulating substrate 1. The insulating substrate 1 has a square shape in a planar direction of the insulating substrate 1. On the one surface 1a that is a surface on one side of the insulating substrate 1, a wiring pattern (not illustrated) made of copper foil is formed in such a manner as to form a circuit on the printed wiring board 10. The one surface 1a serves as a soldering surface of the insulating substrate 1. The electronic component 5 is mounted on the other surface 1b of the insulating substrate 1 which is opposed to the one surface 1a. That is, the printed wiring board 10 is a single-sided printed wiring board on which a wiring pattern forming the circuit is formed only on a single side.

On the one surface 1a of the insulating substrate 1, the land 2 is provided to which the electronic component lead 5a is joined by molten solder 3. The electronic component lead 5a is a lead of the electronic component 5. The land 2 is formed into, for example, a circular shape in the plane on the one surface la of the insulating substrate 1.

In a region of the one surface 1a of the insulating substrate 1 adjacent to the land 2, auxiliary conductors 3 are formed. The auxiliary conductors 3 are disposed at such a position that the molten solder 8 separates from the electronic component lead 5a at the same timing as a timing at which the molten solder 8 separates from the land 2 at a moment when the jet soldering is completed. Further, the through hole 4 is formed at the center of the land 2. The through hole 4 does not have electrical conduction with the other surface 1b of the printed wiring board 10. That is, at the center of the land 2, the through hole 4 is formed, while through-hole plating is not formed on the wall surface of the through hole 4.

The auxiliary conductors 3 are provided to increase the solder-joint amount to join the electronic component lead 5a of the electronic component 5 to the land 2, that is, to increase the solder-joint amount for the printed wiring board 10 and the electronic component 5. The auxiliary conductors 3 are provided in a region of the plane on the one surface 1a of the insulating substrate 1, which is adjacent to the land 2 in a predetermined direction that is perpendicular to a substrate conveying direction 7. The auxiliary conductors 3 are provided to have a width equal to the width of the land 2 in the substrate conveying direction 7 in the same region of the plane on the one surface 1a as the region where the land 2 is formed in the substrate conveying direction 7.

At the auxiliary conductors 3, the molten solder 8 separates from the auxiliary conductors 3 at the same timing as the timing at which the molten solder 8 separates from the electronic component lead 5a, and as the timing at which the molten solder 8 separates from the land 2 at a moment when the jet soldering is completed as described later. In the first embodiment, the auxiliary conductors 3 are formed in a state of being connected to the land 2 in a direction perpendicular to the substrate conveying direction 7.

The electronic component lead 5a of the electronic component 5 to be mounted on the one surface 1a of the printed wiring board 10 is inserted into the through hole 4 from the other surface 1b of the printed wiring board 10. The printed wiring board 10 is conveyed in the substrate conveying direction 7 in a state in which the electronic component lead 5a is inserted into the through hole 4 from the other surface 1b of the printed wiring board 10, while the one surface la is oriented downward, so that jet soldering or the electronic component lead 5a and the land 2 is performed. In the printed wiring board 10, the one surface 1a serves as a soldering surface. The electronic component 5 has, for example, a square shape in the planar direction on the one surface 1aof the printed wiring board 10.

On the one surface 1a of the printed wiring board 10, a solder resist layer 6 is provided similarly to general printed wiring boards. The solder resist layer 6 is an insulating layer covering the one surface 1a of the printed wiring board 10 with only necessary portions being exposed through the insulating layer. The solder resist layer 6 covers the one surface 1a of the printed wiring board 10 with the land 2 and the auxiliary conductors 3 being exposed through the solder resist layer 6. For the sake of easy understanding, illustrations of the solder resist layer 6 are omitted in FIG. 2 and the other subsequent drawings.

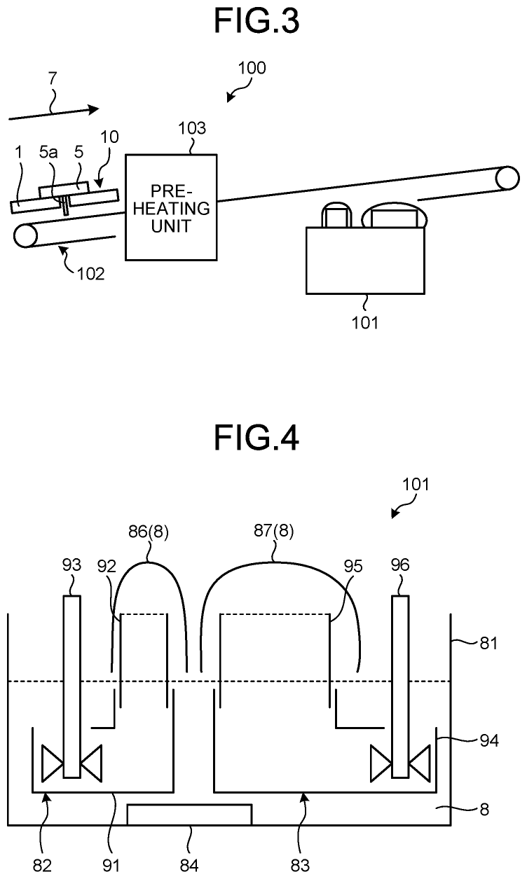

Next, descriptions are made on a jet soldering device 100 that performs soldering on the printed wiring board 10 according to the first embodiment of the present invention. FIG. 3 is a schematic diagram illustrating the configuration of the jet soldering device 100 according to the first embodiment of the present invention. FIG. 4 is a schematic cross-sectional diagram illlustrating the internal structure of a jet soldering unit 101 in the jet soldering device 100 according to the first embodiment of the present invention. The jet soldering device 100 includes the jet soldering unit 101, a conveyor 102, and a preheater 103.

The jet soldering unit 101 is disposed on the downstream side of the preheater 103 in the substrate conveying direction 7 of the printed wiring board 10 that is a soldered workpiece. The jet soldering unit 101 includes: a solder bath 81 in which the molten solder 8 is stored; a first jet portion 82 that is a jet portion through which a primary jet 86 of the molten solder 8 is sprayed onto the printed wiring board 10; a second jet portion 83 that is a jet portion through which a secondary jet 87 of the molten solder 8 is sprayed onto the printed wiring board 10; and a heater 84 to heat the molten solder 8.

The first jet portion 82 is disposed on the upstream side in the conveying direction of the printed wiring board 10. The first jet portion 82 includes: a first partition 91 to separate part of the molten solder 8 to be used in the first jet portion 82 from the other part of the solder bath 81; a primary jet nozzle 92 that is a jet portion through which the primary jet 86 of the molten solder 8 is discharged to supply the molten solder 8 to the printed wiring board 10; and a primary jet pump 93 to generate a flow of the molten solder 8 so as to discharge the primary jet 86 from the primary jet nozzle 92.

The second jet portion 83 is disposed on the downstream side in the conveying direction of the printed wiring board 10. The second jet portion 83 includes: a second partition 94 to separate part of the molten solder 8 to be used in the second jet portion 83 from the other part of the solder bath 81; a secondary jet nozzle 95 that is a jet portion through which the secondary jet 87 of the molten solder 8 is discharged to supply the molten solder 8 to the printed wiring board 10; and a secondary jet pump 96 to generate a flow of the molten solder 8 so as to discharge the secondary jet 87 from the secondary jet nozzle 95.

The molten solder 8 stored in the solder bath 81 is heated by the heater 84, and is partially sprayed up as the primary jet 86 from the primary jet nozzle 92 by a flow of the molten solder 8 generated by the primary jet pump 93. The molten solder 8 stored in the solder bath 81 and heated by the heater 84 is partially sprayed up as the secondary jet 87 from the secondary jet nozzle 95 by a flow of the molten solder 8 generated by the secondary jet pump 96.

The conveyor 102 carries the printed wiring board 10, which is a soldered workpiece applied with flux in advance on its soldering surface, into the preheater 103, and then carries the printed wiring board 10 preheated in the preheater 103 out of the preheater 103. The conveyor 102 carries the printed wiring board 10, having been carried out of the preheater 103, into the jet soldering unit 101, and then carries the printed wiring board 10, having undergone a soldering process in the jet soldering unit 101, out of the jet soldering unit 101. The printed wiring board 10 is conveyed in a state in which the one surface 1a serving as a soldering surface is oriented downward.

The preheater 103 is disposed on the upstream side of the jet soldering unit 101 in the conveying direction of the printed wiring board 10. The preheater 103 performs preheating of the printed wiring board 10 to heat the printed wiring board 10 to a predetermined temperature prior to the soldering process in the jet soldering unit 101. The preheater 103 is capable of setting the heating temperature to any temperature.

Next, descriptions are made on a soldering method for soldering the electronic component lead 5a of the electronic component 5 to the land 2 by using the printed wiring board 10. Soldering on the printed wiring board 10 with the primary jet 86 that is the molten solder 8 in the first jet portion 82 of the jet soldering unit 101 in the jet soldering device 100 is described below as an example of the soldering method.

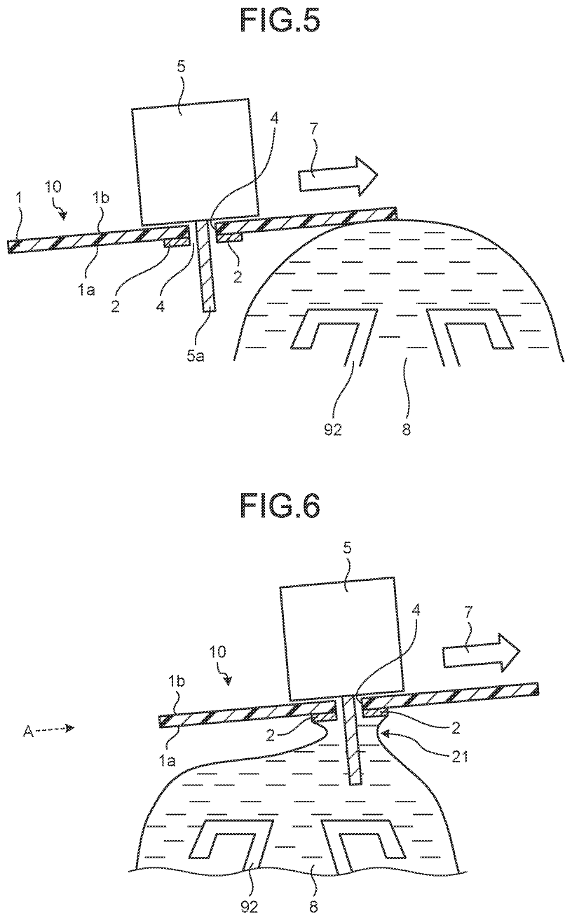

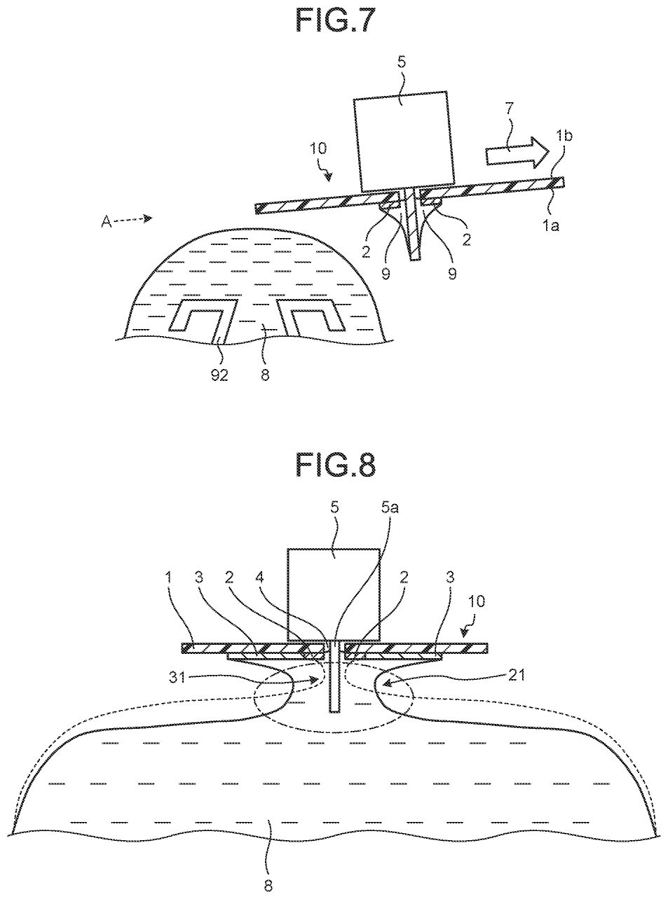

FIGS. 5 to 7 are schematic cross-sectional diagrams illustrating the jet soldering device 100 in a state in which the printed wiring board 10 is conveyed in the substrate conveying direction 7 to undergo jet soldering. FIG. 5 is a diagram of the jet soldering device 100 in which the printed wiring board 10 is conveyed in the substrate conveying direction 7, and illustrates a state at a moment at which the printed wiring board 10 comes into contact with the molten solder 8. FIG. 6 is a diagram of the jet soldering device 100 in which the printed wiring board 10 is conveyed further forward, and the land 2, the auxiliary conductors 3, and the electronic component lead 5a come into contact with the molten solder 8, and illustrates a state at a moment at which the molten solder 8 separates from the land 2, the auxiliary conductors 3, and the electronic component lead 5a after the contact. FIG. 7 is a diagram of the jet soldering device 100 in a state in which the printed wiring board 10 is conveyed even further forward, then soldering is completed with the molten solder 8 having completely separated from the printed wiring board 10, and then a solder fillet 9 is formed on the electronic component lead 5a, the land 2, and the auxiliary conductors 3.

FIG. 8 is a side view illustrating the state illustrated in FIG. 6 when observed from the direction of a broken arrow A in FIG. 6. That is, FIG. 8 illustrates the state of the printed wiring board 10 when observed from the rearward side in the substrate conveying direction 7, and illustrates a state at a moment at which the molten solder 8 separates from the printed wiring board 10. As illustrated in FIG. 8, in the state of the printed wiring board 10 at a moment when the molten solder 8 separates from the printed wiring board 10, the molten solder 8 becomes narrower so as to separate from the land 2, the auxiliary conductors 3, and the electronic component lead 5a, and consequently the molten solder 8 around the electronic component lead 5a forms a narrowed separating shape 21.

FIG. 8 additionally illustrates the molten solder 8 by a broken line when observed from the direction of the broken arrow A in a case where the electronic component lead 5a of the electronic component 5 is soldered to the land 2 on a printed wiring board according to a comparative example in the same manner as the printed wiring board 10. The printed wiring board according to the comparative example has a configuration identical to that of the printed wiring board 10, except that the auxiliary conductors 3 are not provided. Similarly to the printed wiring board 10, on the printed wiring board according to the comparative example, the electronic component lead 5a of the electronic component 5 is inserted into the through hole 4 from the other surface 1b of the printed wiring board 10.

In the state of the printed wiring board according to the comparative example at a moment when the molten solder 8 separates from the printed wiring board according to the comparative example, the molten solder 8 becomes narrower so as to separate from the land 2, and the electronic component lead 5a similarly to the printed wiring board 10, and consequently the molten solder 8 around the electronic component lead 5a forms a narrowed separating shape 31.

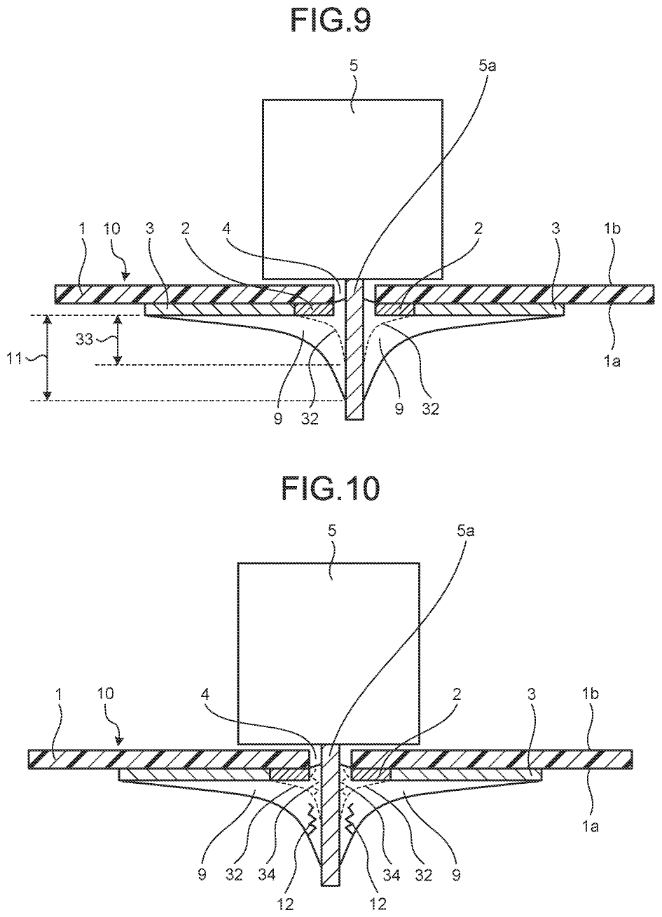

FIG. 9 is a side view illustrating the state illustrated in FIG. 7 when observed from the direction of the broken arrow A in FIG. 7. That is, FIG. 9 illustrates the state of the printed wiring board 10 when observed from the rearward side in the substrate conveying direction 7, and illustrates a state in which soldering on the printed wiring board 10 has been completed. As illustrated in FIG. 9, the solder fillet 9 is formed between the electronic component lead 5a, and the land 2 along with the auxiliary conductors 3. The solder fillet 9 is formed to a solder wetting height 11 along the electronic component lead 5a. The solder wetting height 11 is a height of the solder fillet 9 from the surfaces of the land 2 and the auxiliary conductors 3, that is, a height of the solder fillet 9 from the surfaces of the land 2 and the auxiliary conductors 3 in the thickness direction of the printed wiring board 10.

FIG. 9 additionally illustrates a solder fillet 32 by a broken line when the printed wiring board according to the comparative example is observed from the rearward side in the substrate conveying direction 7. On the printed wiring board according to the comparative example, soldering with the primary jet 86 has been completed. On the printed wiring board according to the comparative example, the solder fillet 32 is also formed between the electronic component lead 5a, and the land 2. The solder fillet 32 is formed to a solder wetting height 33 along the electronic component lead 5a. The solder wetting height 33 is a height of the solder fillet 32 from the surface of the land 2, that is, a height of the solder fillet 32 from the surface of the land 2 in the thickness direction of the printed wiring board 10.

On the printed wiring board 10 on which soldering has been completed as illustrated in FIG. 9, the secondary jet 87 of the molten solder 8 in the second jet portion 83 causes solder to be drawn up into the electronic component lead 5a inserted into the through hole 4 and to be drawn up into the through hole 4 to fill the through hole 4 with the solder, so that eventually soldering of the electronic component 5 to the printed wiring board 10 is completed.

FIG. 10 is a cross-sectional diagram taken along the X-X line in FIG. 1 after the printed wiring board 10 illustrated in FIG. 9 has been incorporated into an electronic device. When the printed wiring board 10 is incorporated into an electronic device, a temperature cycle occurs attributable to a temperature change in the atmosphere due to operation of the electronic device, and attributable to a temperature change in the atmosphere due to installation environment of the electronic device. A crack 12 is generated in the solder fillet 9 that is a solder-joint portion attributable to a linear expansion coefficient mismatch between the electronic component 5 and the printed wiring board 10 in the temperature cycle. The crack 12 in the solder-joint portion spreads over time with the use of the electronic device. The crack 12 spreads in a direction parallel to the direction in which the electronic component lead 5a extends.

FIG. 10 additionally illustrates a state of the solder fillet 32 by a broken line corresponding to the X-X cross-section in FIG. 1 after the printed wiring board according to the comparative example has been incorporated into an electronic device. On the printed wiring board according to the comparative example, soldering has been performed with the solder fillet 32 formed thereon as illustrated in FIG. 9. Similarly to the printed wiring board 10, when the printed wiring board according to the comparative example is incorporated into an electronic device, a temperature cycle occurs attributable to a temperature change in the atmosphere due to operation of the electronic device, and attributable to a temperature change in the atmosphere due to installation environment of the electronic device. A crack 34 is generated in the solder fillet 32 that is a solder-joint portion attributable to a linear expansion coefficient mismatch between the electronic component 5 and the printed wiring board in the temperature cycle. The crack 34 spreads in a direction parallel to the direction in which the electronic component lead 5a extends.

Next, the advantageous effects of the printed wiring board 10 according to the first embodiment are explained. As described above, the auxiliary conductors 3 are provided in a region of the plane on the one surface 1a of the insulating substrate 1, which is adjacent to the land 2 in a predetermined direction that is perpendicular to the substrate conveying direction 7. The auxiliary conductors 3 are provided to nave a width equal to the width of the land 2 in the substrate conveying direction 7 in the same region of the plane on the one surface la as the region where the land 2 is formed in the substrate conveying direction 7. The printed wiring board 10 is conveyed in the substrate conveying direction 7 in a state in which the electronic component lead 5a of the electronic component 5 to be mounted on the other surface 1b of the printed wiring board 10 is inserted into the through hole 4 from the other surface 1b of the printed wiring board 10, while the one surface 1a is oriented downward, so that jet soldering on the electronic component lead 5a and the land 2 is performed.

The auxiliary conductors 3 are provided in the region around the land 2 as described above, so that the molten solder 8 can separate from the electronic component lead 5a, the land 2, and the auxiliary conductors 3 all at the same timing at a moment when the jet soldering is completed as illustrated in FIG. 8. Due to this configuration, the molten solder 8 separating from the electronic component lead 5a, the land 2, and the auxiliary conductors 3 is integrally formed into one piece with a relatively large separating shape 21.

The molten solder 8 integrally forming the separating shape 21 while separating from the electronic component lead 5a, the land 2, and the auxiliary conductors 3 has a length in a direction perpendicular to the substrate conveying direction 7 in the plane on the one surface la of the printed wiring board 10. This length covers the entire region of two auxiliary conductors 3 provided on both sides of the land 2 in a direction perpendicular to the substrate conveying direction 7, and is significantly greater than the length of the separating shape 31. The molten solder 8 with the separating shape 21 separates completely from the printed wiring board 10, so that the solder fillet 9 can be formed as illustrated in FIG. 9. This can increase the solder-joint, amount to join the electronic component lead 5a of the electronic component 5 to the land 2. That is, the solder-joint amount for the printed wiring board 10 and the electronic component 5 can be increased.

That is, on the printed wiring board 10, the auxiliary conductors 3 are provided, so that the molten solder 8 separates from the electronic component lead 5a, the land 2, and the auxiliary conductors 3 at the same timing. Consequently, the solder fillet 9 that is relatively larger in size can be formed with a greater length in a direction perpendicular to the substrate conveying direction 7, and with a greater solder wetting height 11 as compared to the case where the auxiliary conductors 3 are not provided.

In contrast, on the printed wiring board according to the comparative example, since the auxiliary conductors 3 are not provided on the surface of the printed wiring board 10, the separating shape 31 of the molten solder 8 becomes widened beginning from opposite ends of the land 2 in a direction perpendicular to the substrate conveying direction 7 as illustrated in FIG. 8, and thereafter completely separates off from the printed wiring board 10. The solder fillet 32 formed in this case has a length in a direction perpendicular to the substrate conveying direction 7 smaller than the length of the solder fillet 9 described above, and has the solder wetting height 33 smaller than the solder vetting height 11. That is, the solder fillet 32 is relatively smaller in size than the solder fillet 9.

The crack 12 generated in the solder fillet 9 that is a solder-joint portion, and the crack 34 generated in the solder fillet 32 that is a solder-joint portion both spread in parallel to the electronic component lead 5a. Even when the crack 12 generated in the solder fillet 9 and the crack 34 generated in the solder fillet 32 both spread by an equal length, since the solder fillet 9 that is relatively larger in size is formed on the printed wiring board 10, the solder fillet 9 that is a solder-joint portion is not completely broken by the crack 12.

As described above, on the printed wiring board 10, the auxiliary conductors 3 are provided in a region of the plane on the one surface la of the printed wiring board 10, which is adjacent to the land 2 in a direction perpendicular to the substrate conveying direction 7. The auxiliary conductors 3 are provided to have a width equal to the width of the land 2 in the substrate conveying direction 7 in the same region of the plane on the one surface la as the region where the land 2 is formed in the substrate conveying direction 7. On the printed wiring board 10 including the auxiliary conductors 3, the molten solder 8 can separate from the electronic component lead 5a, the land 2, and the auxiliary conductors 3 all at the same timing at a moment when the jet soldering is completed.

Due to this configuration, on the printed wiring board 10, the molten solder 8 separating from the electronic component lead 5a, the land 2, and the auxiliary conductors 3 is integrally formed into one piece with the relatively large separating shape 21. As a result of this, the solder fillet 9 that is relatively larger in size can be formed with a greater length in a direction perpendicular to the substrate conveying direction 7 and a greater solder wetting height 11 as compared to the case where the auxiliary conductors 3 are not provided. This can increase the solder-joint amount to join the electronic component lead 5a of the electronic component 5 to the land 2.

The printed wiring board 10 as described above is incorporated into an electronic device after soldering of the electronic component 5 to the printed wiring board 10 has been completed. Even when the crack 12 is generated in the solder fillet 9 attributable to a linear expansion coefficient mismatch between the electronic component 5 and the printed wiring board 10 in a temperature cycle, and the crack 12 spreads, the solder fillet 9 that is a solder-joint portion is not completely broken. Due to this configuration, the printed wiring board 10 can increase reliability of the joint between the electronic component lead 5a and the land 2 by the solder fillet 9, and can ensure long-term reliability of the joint.

### Second Embodiment

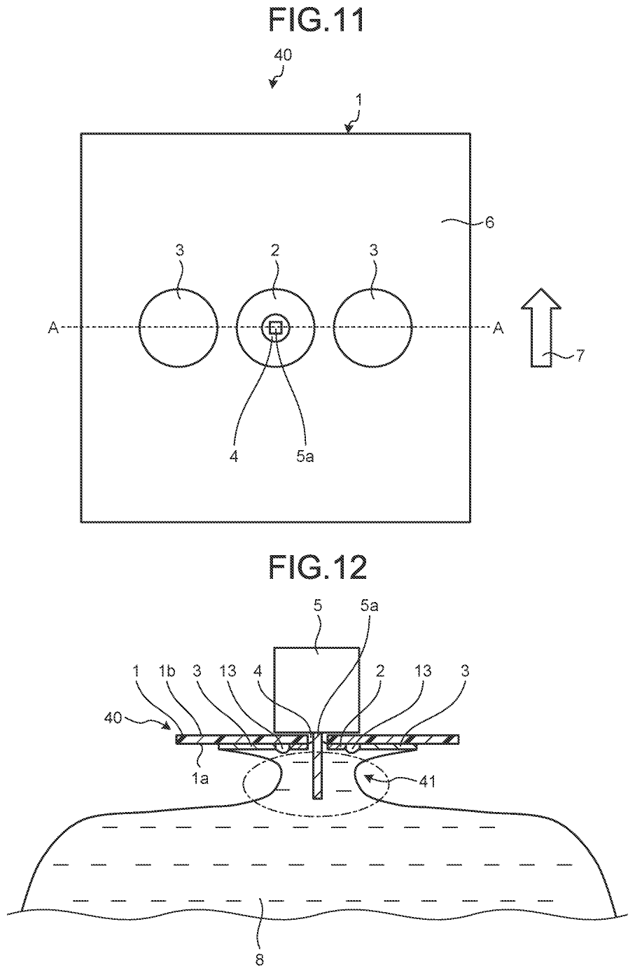

In the first embodiment described above, the case has been described in which the auxiliary conductors 3 are formed in a state of being connected to the land 2 in a direction perpendicular to the substrate conveying direction 7. In a second embodiment of the present invention, a case is described in which the auxiliary conductors 3 are disposed away from the land 2. FIG. 11 is a plan view of relevant parts of a printed wiring board 40 according to the second embodiment of the present invention. FIG. 11 is a diagram corresponding to FIG. 1 and illustrates an enlarged region where the land 2 is formed on the one surface la of the printed wiring board 40. FIG. 11 also illustrates the printed wiring board 40 with the electronic component lead 5a of the electronic component 5 inserted into the through hole 4 on the printed wiring board 40.

The printed wiring board 40 has a configuration identical to that of the printed wiring board 10, except that the auxiliary conductors 3 are provided to be spaced apart from the land 2. That is, on the printed wiring board 40, two auxiliary conductors 3 are provided in a region of the plane or the one surface 1a of the insulating substrate 1, which is adjacent to the land 2 in a direction perpendicular to the substrate conveying direction 7. The two auxiliary conductors 3 are provided to have a width equal to the width of the land 2 in the substrate conveying direction 7 in the same region of the plane on the one surface 1a as the region where the land 2 is formed in the substrate conveying direction 7. The auxiliary conductors 3 are provided on both sides of the land 2 in a direction perpendicular to the substrate conveying direction 7 in a state of being spaced apart from the land 2 in a direction perpendicular to the substrate conveying direction 7.

FIG. 12 is a diagram corresponding to FIG. 8 in soldering of the electronic component 5 to the printed wiring board 40. That is, FIG. 12 illustrates a state of the printed wiring board 40 when observed from the rearward side in the substrate conveying direction 7, and illustrates a state at a moment at which the molten solder 8 separates from the printed wiring board 40. As illustrated in FIG. 12, in the state at a moment when the molten solder 8 separates from the printed wiring board 40, the molten solder 8 becomes narrower so as to separate from the land 2, the auxiliary conductors 3, and the electronic component lead 5a, and consequently the molten solder 3 around the electronic component lead 5a forms a narrowed separating shape 41.

Since on the printed wiring board 40, the land 2 and the auxiliary conductors 3 are disposed to be spaced apart from each other, at a moment when the molten solder 8 separates from the printed wiring board 40, molten solder non-contact regions 13 are formed where the one surface la of the insulating substrate 1 does not come into contact with the molten solder 8. However, the molten solder 8 separates from the auxiliary conductors 3 at the same timing as the timing at which the molten solder 8 separates from the land 2 and the electronic component lead 5a. Therefore, similarly to the printed wiring board 10, the separating shape 41 is formed beginning from opposite ends of the two auxiliary conductors 3 in a direction perpendicular to the substrate conveying direction 7.

Due to this configuration, on the printed wiring board 40, similarly to the first embodiment, the solder fillet 9 that is relatively larger in size can be formed between the electronic component lead 5a, and the land 2 along with the auxiliary conductors 3 as compared to the case where the auxiliary conductors 3 are not provided. This can increase the solder-joint amount to join the electronic component lead 5a of the electronic component 5 to the land 2 in soldering on the printed wiring board 40. That is, the solder-joint amount for the printed wiring board 40 and the electronic component 5 can be increased.

Similarly to the printed wiring board 10, the printed wiring board 40 as described above is incorporated into an electronic device after soldering of the electronic component 5 to the printed wiring board 40 has been completed. Even when a crack is generated in a solder fillet attributable to a linear expansion coefficient mismatch between the electronic component and the printed wiring board 40 in a temperature cycle, and the crack spreads, the solder fillet that is a solder-joint portion is not completely broken. Due to this configuration, the printed wiring board 40 can increase reliability of the joint between the electronic component lead 5a and the land 2 by the solder fillet, and can ensure long-term reliability of the joint.

Examples of the printed wiring board 10 illustrated in the first, embodiment described above, and the printed wiring board 40 illustrated in the second embodiment described above include a single-sided printed wiring board on which a wiring pattern and the land 2 are formed only on a single side. However, a printed wiring board to which the auxiliary conductors 3 are applicable is not limited to this single-sided printed wiring board. For example, the auxiliary conductors 3 may be applicable to a double-sided printed wiring board and a multilayer printed wiring board. As an insulating base material to be used for the insulating substrate 1, it is allowable to use any of the base materials in which a material with insulating properties, for example, a base material of glass woven fabric, glass nonwoven fabric, or paper is impregnated with epoxy resin, polyimide resin, or phenolic resin.

As the material of the molten solder 8 used in the first embodiment and the second embodiment described above, it is possible to use, for example, solder alloy (Sn—3Ag—0.5Cu) that contains silver (Ag) whose mass percentage is 3%, copper (Cu) whose mass percentage is 0.5%, and the remaining mass percentage of tin (on) along with unavoidable impurities. However, the material of the molten solder S is not limited thereto. As the material of the molten solder 3, it. is allowable to use any of Sn—Cu-based solder, Sn—Bi-based solder, Sn—In-based solder, Sn—Sb-based solder, and Sn—Pb-based solder.

Further, examples of the electronic component 5 illustrated in the first embodiment, and the second embodiment described above include an insertion mount component with the electronic component lead 5a. However, an electronic component to be mounted on the printed wiring board 10 and the printed wiring board 40 is not limited thereto. It is allowable on the printed wiring board 10 and the printed wiring board 40 to use a surface mount component for which it is desired to increase the molten-solder joint amount by increasing the size of a solder fillet formed between an electronic component and a printed wiring board.

The configurations described in the above embodiments are only examples of the content of the present invention and techniques of the embodiments can be combined with each other. The configurations can be combined with other well-known techniques, and part of each of the configurations can be omitted or modified without departing from the scope of the present invention.

1. A printed wiring board to which an electronic component is soldered by a jet soldering device, the printed wiring board comprising:
an insulating substrate;
a land provided on one surface of the insulating substrate, the one surface serving as a soldering surface;
a through hole provided in the land and passing through the insulating substrate in a thickness direction of the insulating substrate, where a lead of the electronic component is inserted into the through hole from other surface of the insulating substrate, the other surface being opposed to the one surface;
an auxiliary conductor provided in a region of a plane on the one surface, the region being adjacent to the land in a predetermined direction, the auxiliary conductor being provided to have a width equal to a width of the land in a same region of the plane on the one surface as a region where the land is formed in a direction perpendicular to the predetermined direction; and
a solder resist layer provided on the one surface to cover the one surface with the land and the auxiliary conductors being exposed through thereof, wherein
the predetermined direction is perpendicular to a substrate conveying direction in which the printed wiring board is conveyed for soldering on the printed wiring board by the jet soldering device.

2. The printed wiring board according to claim 1, wherein the auxiliary conductor is provided to be spaced apart from the land in the predetermined direction.

3. (canceled)
